(19) United States
(12) Patent Application Publication
(10) Pub. No.: US 2025/0316460 A1
(43) Pub. Date: Oct. 9, 2025

(54) SUBSTRATE PROCESSING APPARATUS AND SUBSTRATE PROCESSING SYSTEM

(71) Applicant: Tokyo Electron Limited, Tokyo (JP)

(72) Inventor: Satoshi TSUKITA, Miyagi (JP)

(73) Assignee: Tokyo Electron Limited, Tokyo (JP)

(21) Appl. No.: 19/241,422

(22) Filed: Jun. 18, 2025

Related U.S. Application Data
(63) Continuation of application No. PCT/JP2023/044592, filed on Dec. 13, 2023.

(30) Foreign Application Priority Data
Dec. 27, 2022 (JP) 2022-210773

(51) Int. Cl. H01J 37/32; H01L 21/677; H01L 21/683

(52) U.S. Cl. CPC H01J 37/32715; H01J 37/32467; H01J 37/32642; H01J 37/32743; H01L 21/67748; H01L 21/6833; H01J 2237/20235; H01J 2237/204

(57) ABSTRACT

Provided is a substrate processing apparatus comprising: a chamber; a substrate support having a substrate support surface and a ring support surface; a first ring disposed so as to surround a substrate; a second ring disposed on the ring support surface; a plurality of substrate lift pins disposed below the substrate support surface; a plurality of ring lift pins corresponding to the respective substrate lift pins, the plurality of ring lift pins being disposed below the ring support surface; at least one actuator configured to vertically move the substrate lift pins; at least one connection/separation mechanism configured to switch a connected state and a separated state between the substrate lift pin and the corresponding ring lift pin; and a controller configured to perform a substrate transfer sequence, a first ring transfer sequence, and a second ring transfer sequence.

### CROSS-REFERENCE TO RELATED APPLICATIONS

This application is a bypass continuation application of International Application No. PCT/JP2023/044592 having an international filing date of Dec. 13, 2023 and designating the United States, the International Application being based upon and claiming the benefit of priority from Japanese Patent Application No. 2022-210773 filed on Dec. 27, 2022, the entire contents of each are incorporated herein by reference.

### TECHNICAL FIELD

The present disclosure relates to a substrate processing apparatus and a substrate processing system.

### BACKGROUND

Japanese Laid-open Patent Publication No. 2020-113603 discloses a plasma processing apparatus including a wafer placing surface on which a wafer is placed, a ring placing surface, a lift pin, and a driving mechanism. In the plasma processing apparatus disclose in Japanese Laid-open Patent Publication No. 2020-113603, a first ring having a first engagement portion and a second ring having a through-hole that reaches the bottom surface of the first engagement portion are placed on the ring placing surface. The lift pin has a first holding portion to be engaged with the through-hole, and a second holding portion that is connected to the first holding portion in the axial direction and has a protruding portion that protrudes from the outer periphery of the first holding portion.

### SUMMARY

The technique of the present disclosure provides a plasma processing apparatus configured to allow a ring assembly and a substrate on a placing surface to be raised and lowered by a common driving mechanism.

In accordance with an aspect of the present disclosure, there is provided a substrate processing apparatus comprising: a chamber; a substrate support disposed in the chamber and having a substrate support surface and a ring support surface; a first ring disposed so as to surround a substrate on the substrate support surface; a second ring disposed on the ring support surface and having an inner diameter greater than an inner diameter of the first ring and an outer diameter greater than an outer diameter of the first ring, the second ring having an inner annular portion and an outer annular portion, the inner annular portion being configured to support the first ring and having a plurality of through-holes, the outer annular portion being disposed so as to surround the first ring supported on the inner annular portion; a plurality of substrate lift pins disposed below the substrate support surface; a plurality of ring lift pins corresponding to the respective substrate lift pins, the plurality of ring lift pins being disposed below the ring support surface to be aligned with the plurality of through-holes, each lift pin having an upper portion having a first width less than the through-hole and a lower portion having a second width greater than the through-hole; at least one actuator configured to vertically move the substrate lift pins; at least one connection/separation mechanism configured to switch a connected state and a separated state between the substrate lift pin and the corresponding ring lift pin; and a controller configured to perform a substrate transfer sequence, a first ring transfer sequence, and a second ring transfer sequence, wherein the substrate transfer sequence includes: lifting a substrate on the substrate support surface with the substrate lift pins by vertically moving the substrate lift pins in the separated state, the first ring transfer sequence includes: lifting the first ring with the upper portions of the plurality of ring lift pins by simultaneously and vertically moving the substrate lift pins and the ring lift pins in the connected state, and the second ring transfer sequence includes: lifting the second ring with the lower portions of the plurality of ring lift pins by simultaneously and vertically moving the substrate lift pins and the ring lift pins in the connected state.

### BRIEF DESCRIPTION OF THE DRAWINGS

FIG. 1 is an explanatory diagram showing an outline of a configuration of a plasma processing system.

FIG. 2 is an explanatory diagram showing an outline of a configuration of a transfer device.

FIG. 3 is a vertical cross-sectional view showing an outline of a configuration of a plasma processing apparatus according to an embodiment.

FIG. 4 is a partially enlarged view of FIG. 3.

FIG. 5 is an explanatory diagram showing the relationship between a ring lift pin and a through-hole.

FIG. 6 is a front view showing an outline of a configuration of a connection/separation mechanism.

FIG. 7 is a vertical cross-sectional view showing another example of the configuration of the connection/separation mechanism.

FIGS. 8A to 8C are explanatory diagrams showing a substrate transfer sequence.

FIGS. 9A to 9C are explanatory diagrams showing an edge ring transfer sequence.

FIGS. 10A to 10C are explanatory diagrams showing a cover ring transfer sequence.

FIG. 11 is a front view showing another example of the configuration of the connection/separation mechanism.

FIG. 12 is a perspective view showing another example of the configuration of the connection/separation mechanism.

FIG. 13 is a plan view showing the relationship between the lift pins and the transfer pick.

FIG. 14 is a plan view showing the relationship between the lift pins and the transfer pick.

### DETAILED DESCRIPTION

In the manufacturing process of semiconductor devices, plasma processing such as etching using plasma is performed on a semiconductor substrate (hereinafter, simply referred to as “substrate”). The plasma processing is performed in a state where the substrate is placed on a substrate support located in a processing chamber that can be depressurized.

The substrate support has a plurality of annular members arranged to surround the periphery of the substrate on the placing surface in order to obtain satisfactory and uniform processing results at the center and periphery of the substrate during plasma processing. The plurality of annular members include an edge ring located adjacent to the substrate on the placing surface and a cover ring located to cover the outer surface of the edge ring. These annular members wear out by exposure to plasma, and thus require regular replacement. The annular member is replaced using a lifter that raises and lowers the annular member while supporting the annular member, and a transfer mechanism that transfers the annular member, for example.

Here, in the conventional plasma processing apparatus, the driving mechanism of the substrate lifter used for transferring the substrate from the inner space of the processing chamber and the driving mechanism of the annular member lifter used for replacing the annular member are arranged independently, so that improvement is required in terms of space constraints and costs. In addition, in the plasma processing apparatus disclosed in Japanese Laid-open Patent Publication No. 2020-113603, although it is described that the ring assembly as a consumable part is raised and lowered by the lift pin and transferred, there is no description of the relationship with the substrate lift pin.

The technique of the present disclosure has been made in consideration of the above circumstances, and provides a plasma processing apparatus configured such that the substrate and the ring assembly on the placing surface can be raised and lowered by a common driving mechanism. Hereinafter, a plasma processing system as a substrate processing system including the substrate processing apparatus according to the present embodiment will be described with reference to the accompanying drawings. Further, like reference numerals will be given to like parts having substantially the same functions and configurations throughout the present specification and the drawings, and redundant description thereof will be omitted.

### Plasma Processing System

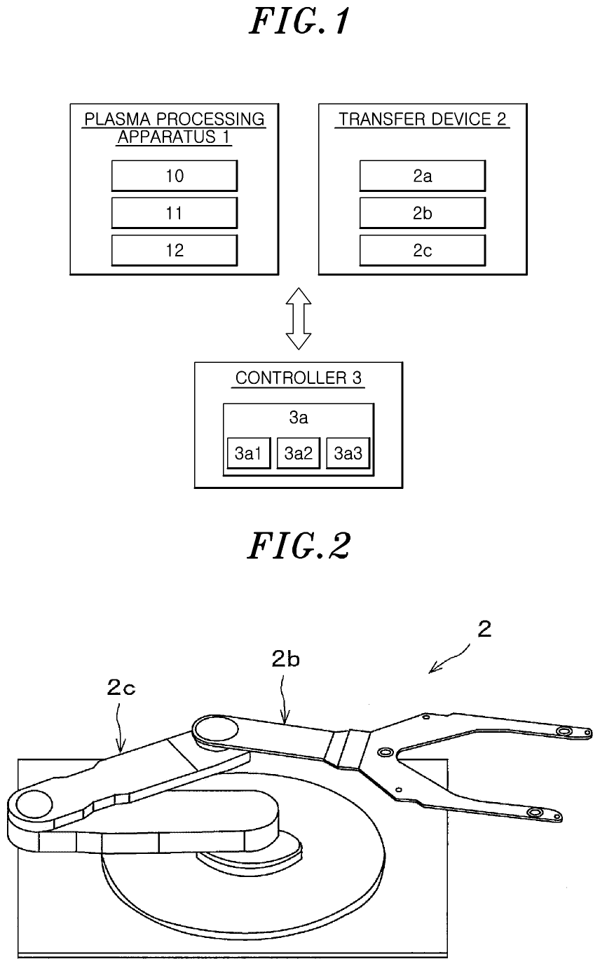

In one embodiment, the plasma processing system includes a plasma processing apparatus 1, a transfer device 2, and a controller 3 as shown in FIG. 1. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port for supplying at least one processing gas to the plasma processing space, and at least one gas exhaust port for exhausting a gas from the plasma processing space. The gas supply port is connected to a gas supply 20 to be described later, and the gas exhaust port is connected to an exhaust system 40 to be described later. The substrate support 11 is disposed in the plasma processing space, and has a substrate support surface for supporting a substrate. A wafer is an example of a substrate.

The plasma generator 12 is configured to generate a plasma from at least one processing gas supplied into the plasma processing space. The plasma generated in the plasma processing space may be capacitively coupled plasma (CCP), inductively coupled plasma (ICP), electron-cyclotron-resonance plasma (ECR plasma), helicon wave plasma (HWP), or surface wave plasma (SWP). In addition, various types of plasma generators including an alternating current (AC) plasma generator and a direct current (DC) plasma generator may be used. In one embodiment, the AC signal (AC power) used in the AC plasma generator has a frequency in the range of 100 kHz to 10 GHz. Thus, the AC signal includes a radio frequency (RF) signal and a microwave signal. In one embodiment, the RF signal has a frequency in the range of 100 kHz to 150 MHz.

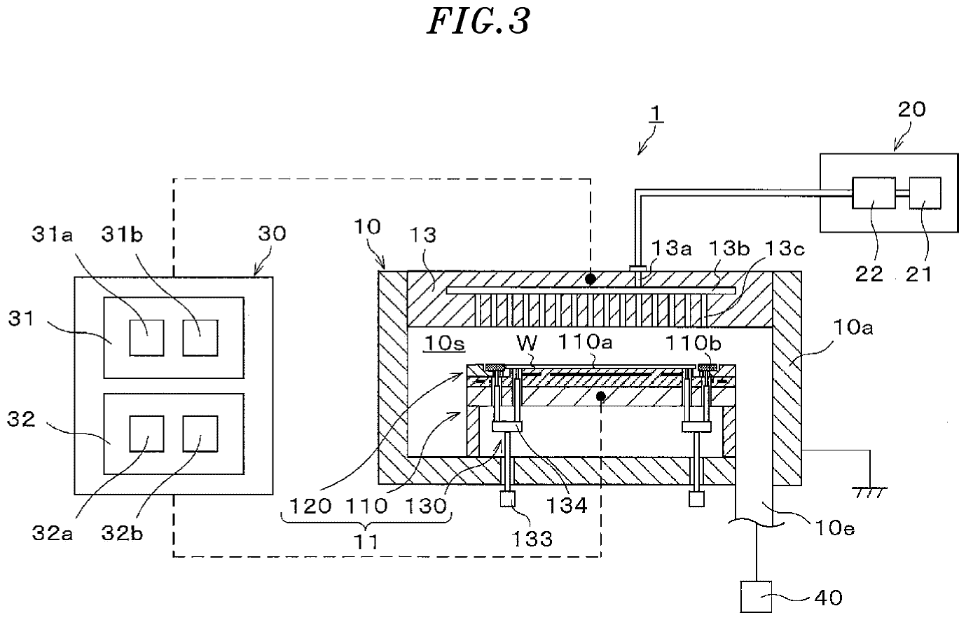

In one example, the transfer device 2 has a transfer chamber 2a, a transfer pick 2b, and a plurality of transfer arms 2c. The transfer chamber 2a has a substrate transfer space, and the transfer pick 2b and the plurality of transfer arms 2c are disposed therein. The transfer chamber 2a is adjacent to the plasma processing chamber 10 of the plasma processing apparatus 1, and is disposed to be able to communicate with the inside (the plasma processing space) of the plasma processing chamber 10. The transfer pick 2b is also referred to as an end effector, and holds and transfers the substrate W and a ring assembly 120 to be described later. As shown in FIG. 2, the transfer pick 2b has a generally U-shape in plan view, and is rotatably connected to the transfer arm 2c disposed at the tip end among the plurality of transfer arms 2c. The plurality of transfer arms 2c have a link arm structure in which they are rotatably connected to each other. Further, the transfer device 2 is configured to transfer the substrate W and the ring assembly 120 between the outside of the plasma processing apparatus 1 and the substrate support 11 disposed in the plasma processing apparatus 1, for example.

Further, in the technique of the present disclosure, the transfer pick 2b and the transfer arm 2c may be collectively referred to as “transfer robot.” In other words, the transfer robot is disposed in the transfer chamber 2a.

The controller 3 processes computer-executable instructions that cause the plasma processing apparatus 1 and the transfer device 2 to perform various steps described in the present disclosure. The controller 3 may be configured to control individual components of the plasma processing apparatus 1 and the transfer device 2 to perform various steps described herein. In one embodiment, the controller 3 may be partially or entirely included in the plasma processing apparatus 1. The controller 3 may include a processing part 3a1, a storage part 3a2, and a communication interface 3a3. The controller 3 is realized by a computer 3a, for example. The processing part 3a1 may be configured to read a program from the storage part 3a2 and execute the read program to perform various control operations. The program may be stored in the storage part 3a2 in advance, or may be acquired via a medium when necessary. The acquired program is stored in the storage part 3a2, and is read from the storage part 3a2 and executed by the processing part 3a1. The medium may be various storage media that are readable by the computer 3a, or may be a communication line connected to the communication interface 3a3. The processing part 3a1 may be a central processing unit (CPU). The storage part 3a2 may include a random access memory (RAM), a read only memory (ROM), a hard disk drive (HDD), a solid state drive (SSD), or a combination thereof. The communication interface 3a3 may communicate with the plasma processing apparatus 1 via a communication line such as a local area network (LAN). Further, the storage medium may a temporary storage medium or a non-temporary storage medium.

### Plasma Processing Apparatus

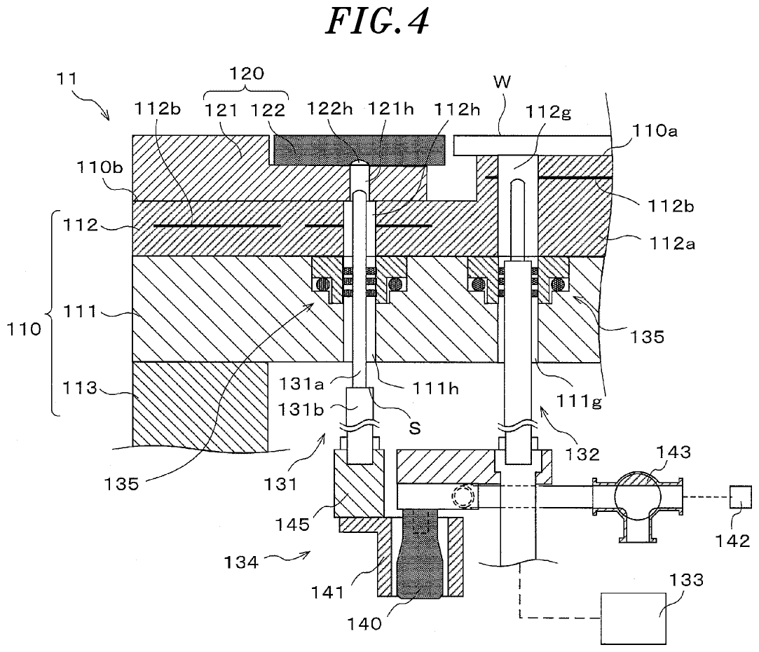

Next, a configuration example of a capacitively coupled plasma processing apparatus 1 will be described as an example of the above-described plasma processing apparatus 1. FIG. 3 is a longitudinal cross-sectional view showing an outline of the configuration of the plasma processing apparatus 1. FIG. 4 is a partially enlarged view showing a part of the configuration of the substrate support 11 shown in FIG. 3.

The capacitively coupled plasma processing apparatus 1 includes a plasma processing chamber 10, a gas supply 20, a power source 30, and an exhaust system 40. The plasma processing apparatus 1 further includes a substrate support 11 and a gas introduction unit. The gas introduction unit is configured to introduce at least one processing gas into the plasma processing chamber 10. The gas introduction unit includes a showerhead 13. The substrate support 11 is disposed in the plasma processing chamber 10. The showerhead 13 is disposed above the substrate support 11. In one embodiment, the showerhead 13 forms at least a part of the ceiling of the plasma processing chamber 10. The plasma processing chamber 10 has a plasma processing space 10s defined by the showerhead 13, a sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a main body 110, a ring assembly 120, and a lifter 130. The main body 110 has a central region 110a for supporting the substrate W and an annular region 110b for supporting the ring assembly 120. The annular region 110b of the main body 110 surrounds the central region 110a of the main body 110 in plan view. The substrate W is disposed on the central region 110a of the main body 110, and the ring assembly 120 is disposed on the annular region 110b of the main body 110 to surround the substrate W on the central region 110a of the main body 110. Thus, the central region 110a is also referred to as “substrate support surface” for supporting the substrate W, and the annular region 110b is also referred to as “ring support surface” for supporting the ring assembly 120.

As shown in FIG. 4, in one embodiment, the main body 110 includes a base 111, an electrostatic chuck 112, and an insulator 113.

The base 111 includes a conductive member. The conductive member of the base 111 may serve as a lower electrode. The electrostatic chuck 112 is disposed on the base 111. The electrostatic chuck 112 includes a ceramic member 112a and an electrostatic electrode 112b disposed in the ceramic member 112a. The ceramic member 112a has the central region 110a. In one embodiment, the ceramic member 112a also has the annular region 110b. Instead of the ceramic member 112a, another member surrounding the electrostatic chuck 112 (central region 110a), such as an annular electrostatic chuck or an annular insulating member, may have the annular region 110b. The ring assembly 120 may be disposed on the annular electrostatic chuck or the annular insulating member, or may be disposed on both the electrostatic chuck 112 and the annular insulating member.

Further, at least one RF/DC electrode connected to an RF source 31 and/or a DC source 32, which will be described later, may be disposed in the ceramic member 112a. In this case, at least one RF/DC electrode serves as the lower electrode. If a bias RF signal and/or a DC signal, which will be described later, is supplied to at least one RF/DC electrode, the RF/DC electrode is also referred to as “bias electrode.” The conductive member of the base 111 and at least one RF/DC electrode may serve as the plurality of lower electrodes. Further, the electrostatic electrode 112b may serve as the lower electrode. Thus, the substrate support 11 includes at least one lower electrode.

A plurality of through-holes 111h and 112h (three in the present embodiment) that penetrate in the thickness direction at portions corresponding to the annular region 110b (ring support surface), and a plurality of through-holes 111g and 112g (three in the present embodiment) that penetrate in the thickness direction at portions corresponding to the central region 110a (substrate support surface) are formed in each of the base 111 and the electrostatic chuck 112. As shown in FIG. 4, a ring lift pin 131 of the lifter 130 which will be described later is inserted into the through-holes 111h and 112h. As shown in FIG. 4, a substrate lift pin 132 of the lifter 130 which will be described later is inserted into the through-holes 111g and 112g.

The insulator 113 is a cylindrical member made of ceramic or the like, and supports the base 111 and the electrostatic chuck 112. The insulator 113 is formed to have an outer diameter equal to the outer diameter of the base 111, for example, and supports the periphery of the base 111 from the bottom. The lower end of the insulator 113 is fastened to the bottom surface (so-called base plate) of the plasma processing chamber 10.

The ring assembly 120 includes a plurality of annular members. As shown in FIG. 4, for example, the ring assembly 120 includes a cover ring 121 and an edge ring 122 as a plurality of annular members. The cover ring 121 and the edge ring 122 are stacked in that order and supported by the annular region 110b (ring support surface). The ring assembly 120 is lifted up from the annular region 110b (ring support surface) by the operation of the lifter 130, and thus can be transferred between the ring assembly 120 and the transfer pick 2b of the transfer device 2 disposed outside the plasma processing apparatus 1.

The cover ring 121 as the second ring is made of an insulating material such as quartz or the like. The cover ring 121 has a stepped portion at the upper portion thereof, and the upper surface of the outer periphery is higher than the upper surface of the inner periphery.

The inner annular portion, which is the inner periphery of the cover ring 121, has an inner diameter greater than the inner diameter of the edge ring 122, and the upper surface forms the support surface of the edge ring 122. In addition, a plurality of through-holes 121h, three in the present embodiment, penetrating in the thickness direction are formed in the inner annular portion that is the inner periphery of the cover ring 121. The through-holes 121h are formed at positions corresponding to the through-holes 111h and 112h formed in the base 111 and the electrostatic chuck 112, respectively, and a first pin portion 131a of the ring lift pin 131 which will be described later is inserted into the through-hole 121h as shown in FIG. 4. The through-hole 121h has a diameter smaller than those of at least the through-holes 111h and 112h.

Therefore, the inner annular portion of the second ring 121 has an inner diameter greater than the inner diameter of the first ring 122, has the plurality of through-holes 121h penetrating in the thickness direction, and supports the first ring 122 from the bottom.

The outer annular portion, which is the outer periphery of the cover ring 121, has a thickness greater than that of the inner annular portion. In addition, the outer diameter of the outer annular portion is greater than the outer diameter of the edge ring 122. The outer annular portion is disposed to surround the periphery of the edge ring 122 supported by the inner annular portion.

Therefore, the outer annular portion of the second ring 121 has an outer diameter greater than the outer diameter of the first ring 122, has a thickness greater than that of the inner annular portion, and is disposed to surround the edge ring 122.

The edge ring 122 as the first ring, which may be referred to as “focus ring”, is supported on the inner annular portion of the cover ring 121 to surround the periphery of the substrate W on the central region 110a, and improves the in-plane uniformity of the plasma processing on the substrate W. The edge ring 122 may be made of a conductive material such as silicon, silicon carbide, or quartz. In addition, as shown in FIG. 4, a plurality of recesses 122h, three in the present embodiment, are formed on the bottom surface of the edge ring 122. The recesses 122h are formed at positions corresponding to the through-holes 121h formed in the cover ring 121, and the tip ends of the first pin portions 131a of the ring lift pins 131 inserted into the through-holes 121h are brought into contact with the recesses 122h.

In one embodiment, in the plasma processing apparatus 1, a plurality of lifters 130, three in the present embodiment, are disposed to correspond to the through-holes 111h and 111g formed in the main body portion 110 of the substrate support portion 11. Each lifter 130 has three ring lift pins 131 corresponding to the through-holes 111h and 112h formed in the annular region 110b (ring support surface) and the through-holes 121h and the recesses 122h of the ring assembly 120, and three substrate lift pins 132 corresponding to the through-holes 111g and 112g formed in the central region 110a (substrate support surface). Further, each lifter 130 has an actuator 133, which is a driving mechanism for vertically moving the ring lift pins 131 and the substrate lift pins 132, a connection/separation mechanism 134 configured to be able to switch the connection/separation state of the ring lift pins 131 and the substrate lift pins 132, and a sealing portion 135.

The ring lift pin 131 includes a plurality of pin portions with different diameters. As shown in FIG. 4, for an example, the ring lift pin 131 includes a first pin portion 131a and a second pin portion 131b as the plurality of pin portions. The first pin portion 131a and the second pin portion 131b extend axially and are integrated.

The first pin portion 131a as the upper portion has a first width W1 (see FIG. 5) smaller than at least a width W3 (see FIG. 5) of the through-hole 121h formed in the cover ring 121. The first pin portion 131a extend axially from the upper surface of the second pin portion 131b, and moves in the vertical direction (axially) together with the second pin portion 131b by the operation of the actuator 133. Further, the first pin portion 131a is configured to be able to protrude from and retract below the upper surface of the inner annular portion of the cover ring 121 through the through-hole 121h. Accordingly, the first pin portion 131a is moved in the vertical direction (lifted up) while supporting the bottom surface of the edge ring 122 supported on the upper surface of the cover ring 121, more specifically the recesses 122h.

The second pin portion 131b as the lower portion has a second width W2 (see FIG. 5) greater than at least the width W3 of the through-hole 121h formed in the cover ring 121. In other words, the second pin portion 131b has on the upper surface thereof a stepped portion S that protrudes radially outward from the outer periphery of the first pin portion 131a. The second pin portion 131b is configured to be able to support the bottom surface of the through-hole 121h (the bottom surface of the cover ring 121) by the stepped portion S. Accordingly, the second pin portion 131b is moved in the vertical direction (lifted up) while supporting the bottom surface of the cover ring 121. The lower end of the second pin portion 131b is supported by the holder 145 as shown in FIG. 4.

The actuator 133 moves at least the substrate lift pins 132 along the axial direction (vertical direction) to raise and lower the substrate W on the electrostatic chuck 112. Accordingly, the substrate W is moved to a transfer height (hereinafter, simply referred to as “transfer height”) where the substrate W is transferred to and from the transfer pick 2b of the transfer device 2. The actuator may be, e.g., an electric actuator, an air cylinder, a motor, or the like. In one embodiment, the actuator 133 is disposed outside the plasma processing chamber 10 as shown in FIG. 3.

Further, when the ring lift pins 131 and the substrate lift pins 132 are connected to each other by a connection/separation mechanism 134 to be described later, the actuator 133 moves the ring lift pins 131 together with the substrate lift pins 132 along the axial direction (vertical direction) to raise and lower the ring assembly 120 on the electrostatic chuck 112. Accordingly, the cover ring 121 or the edge ring 122 is moved to a transfer height where the cover ring 121 or the edge ring 122 is transferred to the transfer pick 2b of the transfer device 2.

In one embodiment, the connection/separation mechanism 134 has an expansion/contraction member 140 connected to the substrate lift pin 132 (more specifically, the actuator 133) and a cylinder 141 connected to the ring lift pin 131.

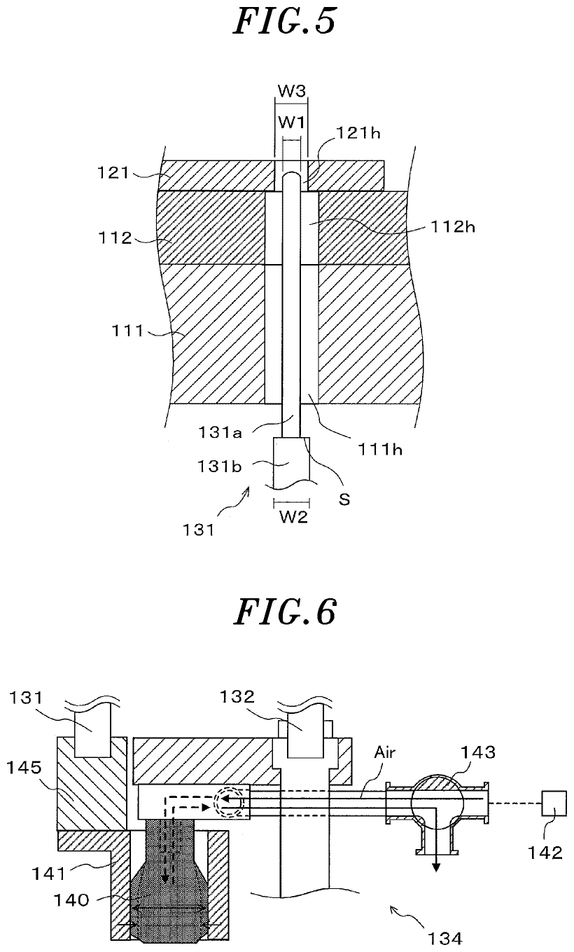

As shown in FIG. 6, the expansion/contraction member 140 is a balloon that repeatedly expands and contracts by injecting and discharging air from an air supply source 142 through a three-way valve 143. In one example, the expansion/contraction member 140 is made of an elastic member such as rubber or the like. The expansion/contraction member 140 is disposed in the cylinder 141 when the substrate lift pin 132 is in a standby state (lowermost position). When the expansion/contraction member 140 expands by injecting air from the air supply source 142, it is pressed against and held by the inner wall surface of the cylinder 141, and becomes integrated with the cylinder 141 (connected state). When the expansion/contraction member 140 contracts by discharging air by the action of the three-way valve 143, it is detached from the inner wall surface of the cylinder 141, and the holding thereof is released (separated state).

As described above, the expansion/contraction member 140 is connected to the substrate lift pin 132 (actuator 133), and moves in the vertical direction together with the substrate lift pin 132 by the operation of the actuator 133.

The cylinder 141 is connected to the ring lift pin 131 via the holder 145. When the cylinder 141 is in a connected state due to the expansion of the expansion/contraction member 140, the cylinder 141 moves in the vertical direction together with the expansion/contraction member 140 by the operation of the actuator 133. When the cylinder 141 is in a separated state due to the contraction of the expansion/contraction member 140, the cylinder 141 does not move in the vertical direction by the operation of the actuator 133, and remains in the standby position.

In other words, in the plasma processing apparatus 1 according to present embodiment, when the expansion/contraction member 140 and the cylinder 141 are in the connected state, the lifter 130 moves the substrate lift pin 132 and the ring lift pin 131 together in the vertical direction by the operation of the actuator 133. On the other hand, when the expansion/contraction member 140 and the cylinder 141 are in the separated state, only the substrate lift pin 132 is moved in the vertical direction.

The number of actuators 133 and connection/separation mechanisms 134 of the lifter 130 is not particularly limited. In other words, for example, the plurality of ring lift pins 131 and the plurality of substrate lift pins 132 may be moved together in the vertical direction by one actuator 133. In this case, as shown in FIG. 7, for example, the plurality of ring lift pins 131 are integrated by an annular member 136 at the lower part of the second pin portion 131b, and the plurality of substrate lift pins 132 are integrated by an annular member 137 at the lower part.

In this case, as shown in FIG. 7, by connecting the cylinder 141 to the annular member 136 and the expansion/contraction member 140 to the annular member 137, the annular member 136 (ring lift pin 131) and the annular member 137 (substrate lift pin 132) can be switched between the connected state and the separated state by the expansion and contraction of the expansion/contraction member 140. In other words, all the ring lift pins 131 and the substrate lift pins 132 can be moved in the vertical direction by one actuator 133.

Further, the arrangement of the expansion/contraction member 140 and the cylinder 141 is not limited to the example shown in the drawing.

As shown in FIG. 4, the sealing portion 135 is provided in the through-holes 111h and 111g to prevent communication between the upper space (plasma processing space 10s) in a vacuum atmosphere and the lower space (below the substrate support 11) in an atmospheric atmosphere. The sealing portion 135 is, e.g., an axis seal or a bellows.

The substrate support 11 may include a temperature control module configured to control at least one of the electrostatic chuck 112, the ring assembly 120, and the substrate W to a target temperature. The temperature control module may include a heater, a heat transfer medium, a channel, or a combination thereof. A heat transfer fluid, such as brine or a gas, flows through the channel. In one embodiment, the channel is formed in the base 111, and one or multiple heaters are disposed in the ceramic member 112a of the electrostatic chuck 112. Further, the substrate support 11 may include a heat transfer gas supply configured to supply a heat transfer gas (backside gas) to the gap between the backside of the substrate W and the upper surface of the electrostatic chuck 112.

Referring back to the description of FIG. 3, the showerhead 13 is configured to introduce at least one processing gas from the gas supply 20 into the plasma processing space 10s. The showerhead 13 has at least one gas supply port 13a, at least one gas diffusion space 13b, and a plurality of gas inlet ports 13c. The processing gas supplied from the gas supply 20 to the gas supply port 13a passes through the gas diffusion space 13b and is introduced into the plasma processing space 10s from the plurality of gas inlet ports 13c. Further, the showerhead 13 includes at least one upper electrode. The gas introduction unit may include, in addition to the showerhead 13, one or multiple side gas injectors (SGI) attached to one or multiple openings formed in the sidewall 10a.

The gas supply 20 may include at least one gas source 21 and at least one flow rate controller 22. In one embodiment, the gas supply 20 is configured to supply at least one processing gas from the corresponding gas source 21 to the showerhead 13 through the corresponding flow rate controller 22. The flow rate controllers 22 may include, for example, a mass flow controller or a pressure-controlled flow rate controller. Further, the gas supply 20 may include at least one flow modulation device for modulating the flow rate of at least one processing gas or causing it to pulse.

The power source 30 includes an RF source 31 connected to the plasma processing chamber 10 through at least one impedance matching circuit. The RF source 31 is configured to supply at least one RF signal (RF power) to at least one lower electrode and/or at least one upper electrode. Accordingly, plasma is produced from at least one processing gas supplied to the plasma processing space 10s. Thus, the RF source 31 may serve as at least a part of the plasma generator 12. In addition, by supplying a bias RF signal to at least one lower electrode, a bias potential is generated at the substrate W, and ion components in the produced plasma can be attracted to the substrate W.

In one embodiment, the RF source 31 includes a first RF generator 31a and a second RF generator 31b. The first RF generator 31a is connected to at least one lower electrode and/or at least one upper electrode through at least one impedance matching circuit, and is configured to generate a source RF signal (source RF power) for plasma generation. In one embodiment, the source RF signal has a frequency within a range of 10 MHz to 150 MHz. In one embodiment, the first RF generator 31a may be configured to generate a plurality of source RF signals having different frequencies. The generated one or multiple source RF signals are provided to at least one lower electrode and/or at least one upper electrode.

The second RF generator 31b is connected to the at least one lower electrode through at least one impedance matching circuit, and is configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency within a range of 100 kHz to 60 MHz. In one embodiment, the second RF generator 31b may be configured to generate a plurality of bias RF signals having different frequencies. The generated one or multiple bias RF signals are supplied to at least one lower electrode. In various embodiments, at least one of the source RF signal and the bias RF signal may be pulsed.

Further, the power source 30 may include a DC source 32 connected to the plasma processing chamber 10. The DC source 32 includes a first DC generator 32a and a second DC generator 32b. In one embodiment, the first DC generator 32a is connected to at least one lower electrode, and is configured to generate a first DC signal. The generated first DC signal is applied to at least one lower electrode. In one embodiment, the second DC generator 32b is connected to at least one upper electrode, and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a rectangular pulse waveform, a trapezoidal pulse waveform, a triangular pulse waveform, or a combination thereof. In one embodiment, a waveform generator for generating a sequence of voltage pulses from the DC signal is connected between the first DC generator 32a and at least one lower electrode. Therefore, the first DC generator 32a and the waveform generator constitute a voltage pulse generator. When the second DC generator 32b and the waveform generator constitute a voltage pulse generator, the voltage pulse generator is connected to at least one upper electrode. The voltage pulse may have positive polarity or negative polarity. Further, the sequence of voltage pulses may include one or multiple positive polarity voltage pulses and one or multiple negative polarity voltage pulses in one cycle. The first and second DC generators 32a and 32b may be provided in addition to the RF source 31, and the first DC generator 32a may be provided instead of the second RF generator 31b.

The exhaust system 40 may be connected to a gas exhaust port 10e provided at the bottom portion of the plasma processing chamber 10, for example. The exhaust system 40 may include a pressure control valve and a vacuum pump. The pressure in the substrate processing space 10s is adjusted by the pressure control valve. The vacuum pump may include a turbomolecular pump, a dry pump, or a combination thereof.

While various embodiments have been described above, the present disclosure is not limited to the above-described embodiments, and various additions, omissions, substitutions and changes may be made. Further, other embodiments can be implemented by combining elements in different embodiments.

### Transfer Operation by Lifter 130

Next, the substrate transfer sequence, the first ring transfer sequence, and the second ring transfer sequence, which are the transfer operations of the substrate W and the ring assembly 120 performed using the lifter 130, will be described. The operation of the lifter 130 to perform the various transfer sequences is performed under the control of the controller 3, for example.

### (1) Substrate Transfer Sequence

First, the operation of transferring the substrate W with respect to the substrate support 11 will be described.

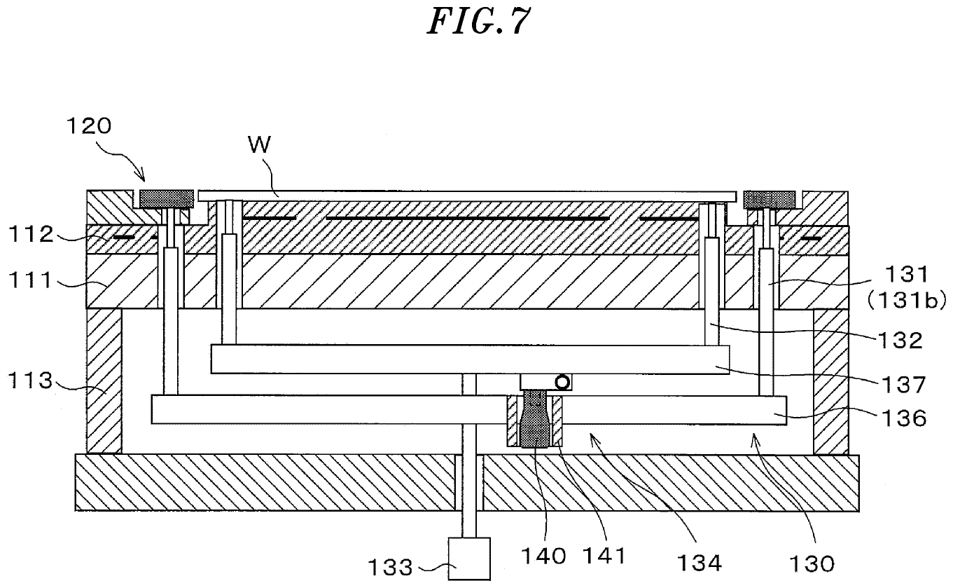

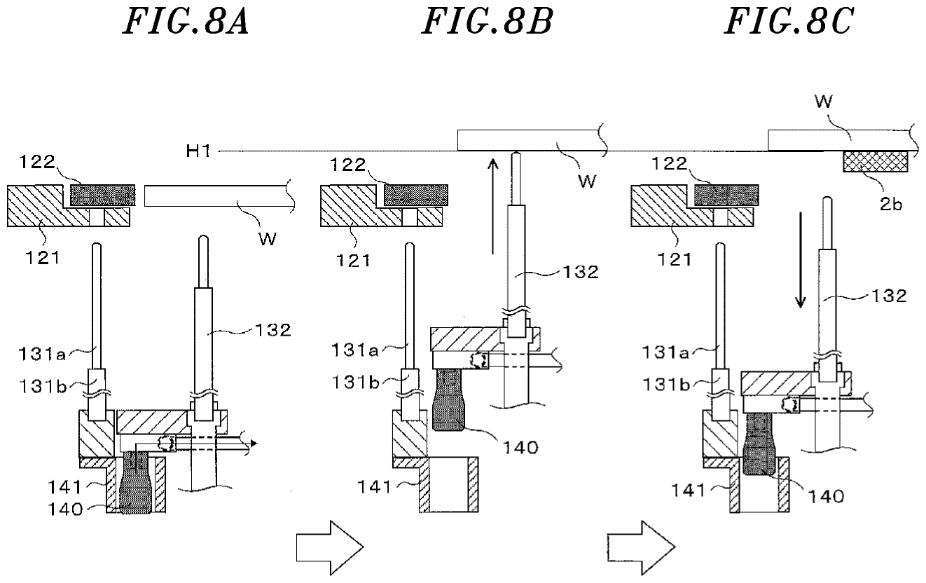

In the case of unloading the substrate W placed on the central region 110a of the substrate support 11 from the plasma processing chamber 10, first, air is discharged from the expansion/contraction member 140 as shown in FIG. 8A to separate the expansion/contraction member 140 and the cylinder 141.

Next, the actuator 133 is driven, so that the substrate lift pins 132 are raised in the vertical direction (axial direction) from the standby position. At this time, since the expansion/contraction member 140 and the cylinder 141 are separated, the substrate lift pins 132 are raised independently from the ring lift pins 131. As a result, the substrate W on the central region 110a is transferred to the substrate lift pins 132, and the substrate W is lifted to a transfer height H1, as shown in FIG. 8B. The transfer height H1 is the height at which the transfer pick 2b does not interfere with the object to be transferred (the substrate W or the ring assembly 120) when the transfer pick 2b enters or retracts from the gap between the upper surface of the substrate support 11 and the object to be transferred supported by the lifter 130. After the substrate W is lifted to the transfer height, the transfer pick 2b of the transfer device 2 enters the position below the substrate W supported by the substrate lift pins 132, and the substrate lift pins 132 are lowered by the actuator 133, so that the substrate W is transferred from the substrate lift pins 132 to the transfer pick 2b as shown in FIG. 8C.

Then, the substrate W transferred to the transfer pick 2b is transferred from the plasma processing chamber 10 to the transfer chamber 2a.

On the other hand, in the case of loading the substrate W into the plasma processing chamber 10 and placing the substrate W on the central region 110a of the substrate support 11, the reverse sequence of the operations shown in FIGS. 8A to 8C is executed.

In other words, after the transfer pick 2b holding the substrate W is inserted into the plasma processing chamber 10, the substrate lift pins 132 are raised to receive the substrate W on the transfer pick 2b (see FIG. 8C). Then, the transfer pick 2b is retracted, and the substrate lift pins 132 are lowered to place the substrate W on the central region 110a (see FIG. 8B). In this case, it is desirable that the expansion/contraction member 140 and the cylinder 141 are separated (see FIG. 8A).

### (2) Edge Ring 122 (First Ring) Transfer Sequence

Next, the operation of transferring the edge ring 122 with respect to the substrate support 11 will be described.

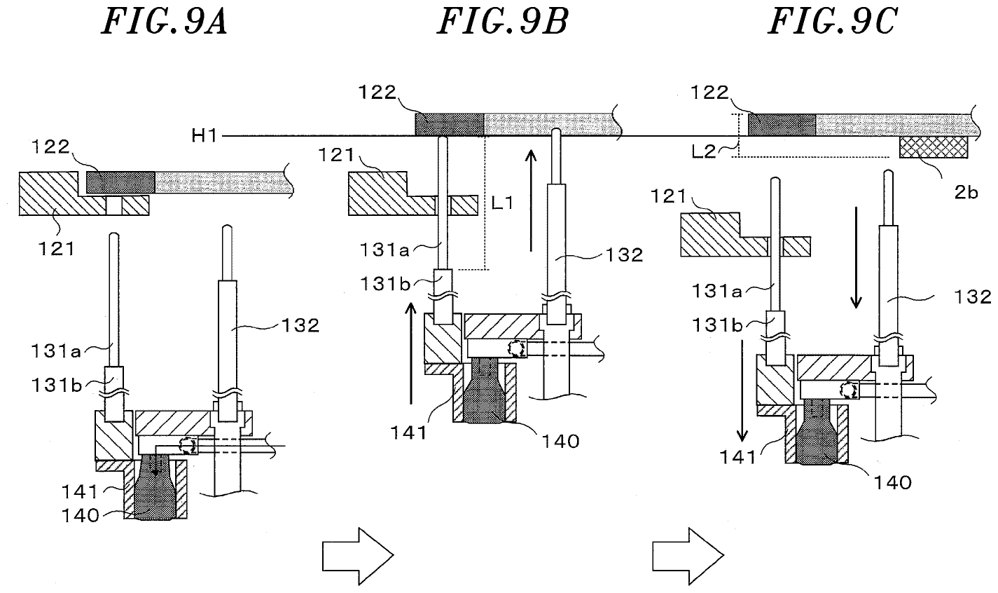

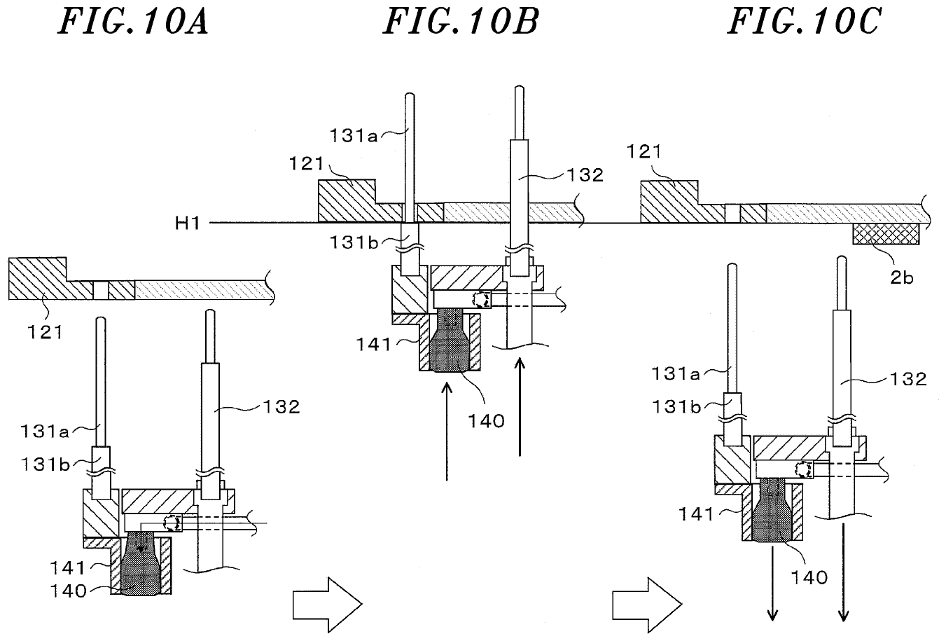

In the case of unloading the edge ring 122 placed on the inner annular portion of the cover ring 121 on the annular region 110b of the substrate support 11 from the plasma processing chamber 10, first, air is injected into the expansion/contraction member 140 as shown in FIG. 9A to connect the expansion/contraction member 140 and the cylinder 141.

Next, the actuator 133 is driven, so that the substrate lift pins 132 are raised in the vertical direction (axial direction) from the standby position. In this case, since the expansion/contraction member 140 and the cylinder 141 are connected, the ring lift pins 131 are raised in the vertical direction from the standby position together with the substrate lift pins 132. Further, in this case, since the first pin portion 131a of the ring lift pin 131 has the first width W1 smaller than that of the through-hole 121h formed in the cover ring 121, the edge ring 122 is transferred to the first pin portions 131a of the ring lift pins 131 through the through-holes 121h, and the edge ring 122 is lifted to the transfer height H1 as shown in FIG. 9B.

After the edge ring 122 is lifted to the transfer height, the transfer pick 2b of the transfer device 2 enters the position below the edge ring 122 supported by the first pin portion 131a of the ring lift pin 131, and the ring lift pin 131 is lowered by driving the actuator 133, so that the edge ring 122 is transferred from the ring lift pin 131 to the transfer pick 2b as shown in FIG. 9C.

Then, the edge ring 122 transferred to the transfer pick 2b is transferred from the plasma processing chamber 10 to the transfer chamber 2a.

Here, when the edge ring 122 is supported by the first pin portion 131a of the ring lift pin 131, the cover ring 121 may be supported and lifted by the stepped portion S of the second pin portion 131b due to the length L1 of the first pin portion 131a (see FIG. 9B). Therefore, if the distance between the bottom surface of the edge ring 122 supported by the first pin portion 131a and the upper surface of the cover ring 121 supported by the second pin portion 131b is small, the transfer pick 2b and the cover ring 121 interfere with each other and the edge ring 122 may not be transferred appropriately.

Therefore, it is desirable that the length L1 of the first pin portion 131a, which determines the distance between the bottom surface of the edge ring 122 and the upper surface of the cover ring 121, is greater than at least the total thickness L2 of the transfer pick 2b and the cover ring 121 (see FIG. 9C), and that the difference between the length L1 and the total thickness L2 is set to be minimized in order to efficiently transfer the cover ring 121 later. However, this does not apply when the transfer pick 2b and the cover ring 121 do not interfere with each other even when the cover ring 121 is held by the stepped portion S.

In the case of loading the edge ring 122 into the plasma processing chamber 10 and placing the edge ring 122 on the annular region 110b of the substrate support portion 11, it is necessary to execute the reverse sequence of the operations shown in FIGS. 9A to 9C. However, it is desirable to load the edge ring 122 together with the cover ring 121 constituting the ring assembly 120.

### (3) Cover Ring 121 (Second Ring) Transfer Sequence

Finally, the operation of transferring the cover ring 121 with respect to the substrate support 11 will be described.

In the case of unloading the cover ring 121 placed on the annular region 110b of the substrate support 11 from the plasma processing chamber 10, first, air is injected into the expansion/contraction member 140 as shown in FIG. 10A to connect the expansion/contraction member 140 and the cylinder 141.

Next, the actuator 133 is driven, so that the substrate lift pins 132 are raised in the vertical direction (axial direction) from the standby position. In this case, since the expansion/contraction member 140 and the cylinder 141 are connected, the ring lift pins 131 are raised in the vertical direction from the standby position together with the substrate lift pins 132. In this case, since the second pin portion 131b of the ring lift pin 131 has the second width W2 greater than that of the through-hole 121h formed in the cover ring 121, the cover ring 121 is transferred to the second pin portion 131b of the ring lift pin 131, and the cover ring 121 is lifted to the transfer height H1 as shown in FIG. 10B.

After the cover ring 121 is lifted to the transfer height, the transfer pick 2b of the transfer device 2 enters the position below the cover ring 121 supported by the second pin portion 131b of the ring lift pin 131, and the ring lift pin 131 is lowered by driving the actuator 133, so that the cover ring 121 is transferred from the ring lift pin 131 to the transfer pick 2b as shown in FIG. 10C.

The cover ring 121 transferred to the transfer pick 2b is then transferred from the plasma processing chamber 10 to the transfer chamber 2a.

Here, if the length of the first pin portion 131a of the ring lift pin 131 is set to be greater than the total thickness described above and the difference between the length of the first pin portion 131a and the total thickness is also set to be large, the relative support height of the cover ring 121 in the axial direction of the ring lift pin 131 is lowered. Therefore, the increase in the height of the ring lift pin 131 which is required to lift the cover ring 121 to the transfer height H1 increases, and the transfer efficiency of the cover ring 121 decreases.

In consideration of the above, it is desirable that the difference between the length of the first pin portion 131a and the total thickness L2 is set to be minimized as described above.

Further, in the case of loading the cover ring 121 into the plasma processing chamber 10 and placing the cover ring 121 on the annular region 110b of the substrate support portion 11, it is necessary to execute the reverse sequence of the operation shown in FIGS. 10A to 10C. However, it is desirable to load the cover ring 121 together with the edge ring 122 constituting the ring assembly 120.

Specifically, after the transfer pick 2b holding the ring assembly 120 is inserted into the plasma processing chamber 10, the ring lift pins 131 connected to the substrate lift pins 132 are raised to receive the ring assembly 120 on the transfer pick 2b. In this case, the edge ring 122 is supported by the first pin portions 131a via the through-holes 121h of the cover ring 121, and the cover ring 121 is supported by the second pin portions 131b. Thereafter, the transfer pick 2b is retracted and the ring lift pins 131 are lowered, so that the cover ring 121 and the edge ring 122 are sequentially placed on the annular region 110b.

The transfer operation of the substrate W and the ring assembly 120 by the lifter 130 is controlled as described above.

As described above, in the plasma processing apparatus 1 according to present embodiment, the substrate lift pins 132 for lifting and lowering the substrate W and the ring lift pins 131 for lifting and lowering the ring assembly 120 are configured to be connected and separated by the connection/separation mechanism 134. Hence, there is no need to independently provide the actuator 133 for lifting and lowering them, which makes it possible to arrange other components (improve space constraints) and reduce costs. Further, in the present embodiment, the connection/separation mechanism 134 has a so-called pneumatic chuck structure including the expansion/contraction member 140 and the cylinder 141, so that the component arrangement for miniaturization and weight reduction can be easily realized. In addition, the chucking part has a high degree of freedom, and the lift pin height can be easily adjusted by setting the mechanical stop.

Further, in the plasma processing apparatus 1 of the present embodiment, as described above, the ring lift pins 131 and the substrate lift pins 132 (hereinafter, simply referred to as “lift pins”) are arranged from the lower part of the substrate support 11 in an atmospheric atmosphere toward the plasma processing space 10s in a vacuum atmosphere via the sealing part 135. Therefore, when a pressure difference occurs between the inside and outside of the plasma processing chamber 10 during plasma processing, for example, the lift pins are subjected to a first stress (vacuum force about 70 gf, for example, in the plasma processing chamber 10) in a direction in which they are pulled into the plasma processing chamber 10. In particular, when the plasma processing space 10s is evacuated during the start-up of the plasma processing apparatus 1, the lift pins are instantaneously subjected to a second stress (about 280 gf, for example) greater than the first stress (vacuum force).

In this regard, the substrate lift pins 132 are connected to the actuator 133 as described above, and the actuator 133 is fastened to the bottom surface of the plasma processing chamber 10, so that the substrate lift pins 132 can be suppressed from being attracted into the plasma processing chamber 10 against the first and second stresses due to their own weight (weight including the actuator 133).

On the other hand, if the ring lift pins 131 are subjected to the first or second stress in the attracting direction particularly when they are separated from the substrate lift pins 132, the tip end heights of the pins change, which may result in a state in which the ring assembly 120 is not appropriately transferred to the transfer pick 2b of the transfer device 2.

Therefore, in the plasma processing apparatus 1 of the present disclosure, it is desirable that the ring lift pins 131 are heavy enough not to be lifted at least by the vacuum force, that is, the gravity due to the weight becomes greater than equal to the first stress (e.g., about 100 g or more). Accordingly, the attraction of the ring lift pins 131 due to the vacuum force can be suppressed even when they are separated from the substrate lift pins 132 during plasma processing, for example.

The weight of the ring lift pins 131 can be increased by scaling up the holder 145 for holding the ring lift pins 131 or the cylinder 141 connected to the holder 145, or by forming the holder 145 and the cylinder 141 using a heavy material, such as stainless steel (SUS) or the like.

In addition, in the plasma processing apparatus 1 of the present disclosure, the weight of the ring lift pins 131 may be further increased (for example, 300 g or more) to cope with the second stress that is instantaneously applied by the evacuation during the start-up of the plasma processing apparatus 1. Accordingly, the attraction of the ring lift pins 131 can be suppressed even when they are separated from the substrate lift pins 132 during plasma processing, for example.

However, the holder 145 or the cylinder 141 may be scaled up in the case of coping with the second stress using the weight. In view of the above, it is possible to cope with the second stress by the integration with the substrate lift pins 132 (switching to the connected state) instead of coping with the second stress using the weight.

Specifically, at the time of starting up the plasma processing apparatus 1, air is injected into the expansion/contraction member 140, prior to the evacuation of the plasma processing chamber 10, to connect the expansion/contraction member 140 and the cylinder 141 (the ring lift pins 131 and the substrate lift pins 132). Accordingly, the weight of the substrate lift pins 132 or the actuator 133 is added to the effective weight of the ring lift pins 131, thereby suppressing the attraction of the ring lift pins 131 during the start-up of the plasma processing apparatus 1.

In the example shown in the above embodiment, the lower parts of the ring lift pins 131 are held by the holder 145 as described above, and the weight of the holder 145 is used for coping with the first gravity. However, in this case, it may be necessary to scale up the holder 145 or the cylinder 141 due to the increase in weight as described above.

Therefore, in the technique of the present disclosure, a biasing member may be provided, instead of the holder 145, under the ring lift pins 131.

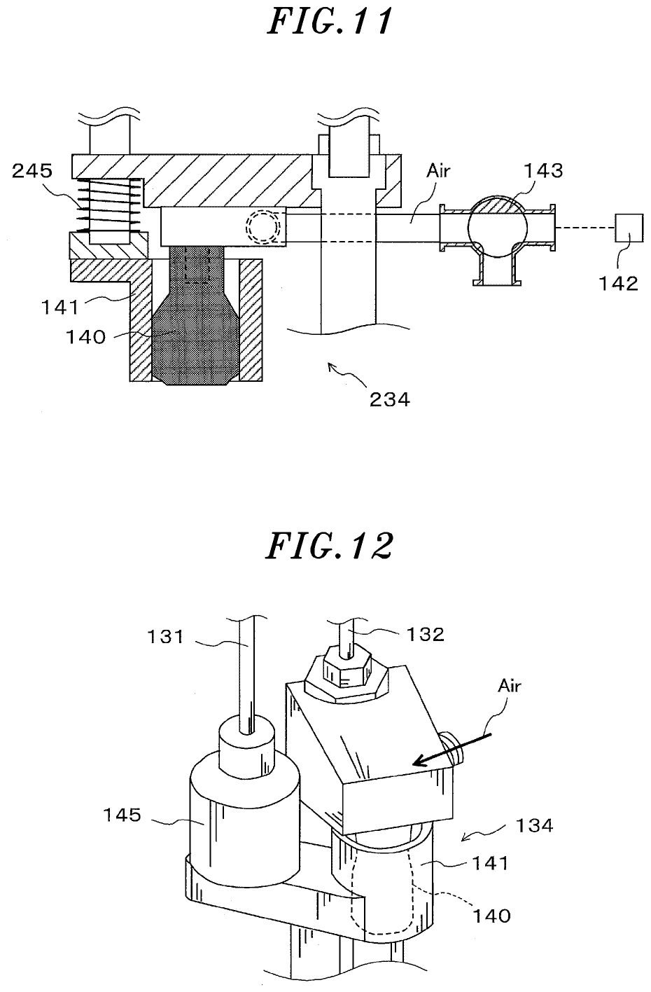

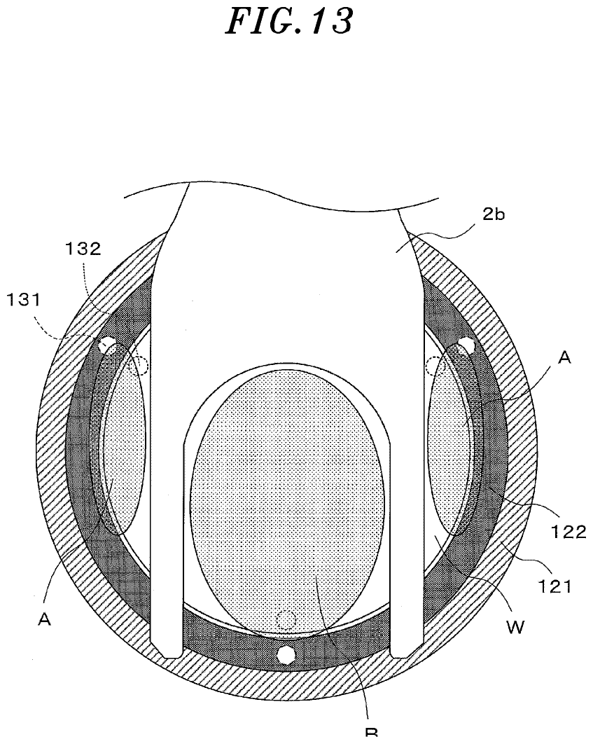

FIG. 11 is an explanatory diagram showing an outline of a configuration of a connection/separation mechanism 234 according to another embodiment.

As shown in FIG. 11, the connection/separation mechanism 234 according to another embodiment has a biasing member 245 such as a spring or the like, instead of the holder 145. The biasing member 245 biases the ring lift pins 131 in a direction of the reaction force (in a direction opposite) to the vacuum force in the plasma processing space 10s in the plasma processing chamber 10 in the case of moving only the substrate lift pins 132 in the vertical direction in a state where the expansion/contraction member 140 and the cylinder 141 are separated.

Further, in the connection/separation mechanism 234, in the case of moving only the substrate lift pins 132 in the vertical direction, the biasing member 245 is selected such that the reaction force (spring force) acting on the ring lift pins 131 becomes greater than or equal to the vacuum force (e.g., 1.0 N or greater), which is the first stress. Accordingly, the attraction of the substrate lift pins 132 due to the vacuum force can be suppressed even when they are separated from the substrate lift pins 132 during plasma processing.

In the above embodiment, the case in which the ring lift pins 131, the connection/separation mechanism 134, and the substrate lift pins 132 are arranged substantially linearly in plan view is illustrated as shown in FIG. 4, for example. However, the arrangement of the ring lift pins 131, the connection/separation mechanism 134, and the substrate lift pins 132 is not limited.

Specifically, as shown in FIG. 12, for example, the ring lift pin 131, the connection/separation mechanism 134, and the substrate lift pin 132 may be arranged in a substantially triangular shape in plan view.

By arranging the ring lift pin 131, the connection/separation mechanism 134, and the substrate lift pin 132 in a substantially triangular shape, the linear distance between the ring lift pin 131 and the substrate lift pin 132 can be reduced, which makes it possible to minimize the connection/separation mechanism 134 and improve the strength of the components.

Further, by reducing the linear distance between the ring lift pin 131 and the substrate lift pin 132, the interference between the substrate lift pin 132 and the transfer pick 2b during the transfer of the substrate W or ring assembly 120 can be suppressed, as shown in FIG. 13.

More specifically, when the ring lift pin 131, the connection/separation mechanism 134, and the substrate lift pin 132 are arranged substantially linearly in plan view as described above, the linear distance between the ring lift pin 131 and the substrate lift pin 132 increases compared to when they are arranged in a substantially triangular shape in plan view. Accordingly, the substrate lift pin 132 and the transfer pick 2b interfere with each other (overlap in plan view) in the vertical direction, and the object to be transferred may not be appropriately transferred.

Therefore, in the plasma processing apparatus 1 of the present disclosure, the linear distance between the ring lift pin 131 and the substrate lift pin 132 is reduced by arranging the ring lift pin 131, the connection/separation mechanism 134, and the substrate lift pin 132 in a substantially triangular shape in plan view. Accordingly, it is possible to minimize the connection/separation mechanism 134, improve the strength of the components, and suppress the interference between the substrate lift pins 132 and the transfer pick 2b.

In this case, at least two of the plurality of substrate lift pins 132 (three in the present embodiment) are disposed in the outer region A of the U-shaped transfer pick 2b, and at least one of them is disposed in the inner region B, as shown in FIG. 13.

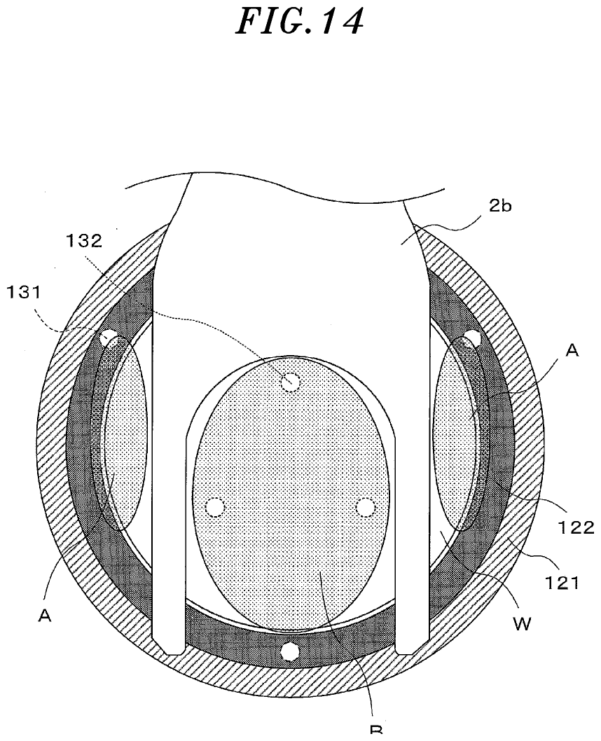

In addition, in order to suppress the vertical interference between the substrate lift pins 132 and the transfer pick 2b, all the plurality of substrate lift pins 132 (three in the present embodiment) may be arranged in the inner region B of the transfer pick 2b as shown in FIG. 14.

However, in this case, the linear distance between the ring lift pin 131 and the substrate lift pin 132 increases in the configuration of the connection/separation mechanism 134. Therefore, in order to miniaturize the mechanism, it is desirable to arrange at least one of the substrate lift pins 132 in the outer region A by arranging the ring lift pins 131, the connection/separation mechanism 134, and the substrate lift pins 132 in a substantially triangular shape.

It should be noted that the above-described embodiments are illustrative in all respects and are not restrictive. The above-described embodiments may be omitted, replaced, or changed in various forms without departing from the scope of the appended claims and the gist thereof. For example, the components of the above-described embodiments can be randomly combined. The effects of the components for arbitrary combination can be obtained from the corresponding arbitrary combination, other effects apparent to those skilled in the art can also be obtained.

Further, the effects described in the present specification are merely explanatory or exemplary, and are not restrictive. In other words, in the technique related to the present disclosure, other effects apparent to those skilled in the art can be obtained from the description of the present specification in addition to the above-described effects or instead of the above-described effects.

1. A substrate processing apparatus comprising:
a chamber;
a substrate support disposed in the chamber and having a substrate support surface and a ring support surface;
a first ring disposed so as to surround a substrate on the substrate support surface;
a second ring disposed on the ring support surface and having an inner diameter greater than an inner diameter of the first ring and an outer diameter greater than an outer diameter of the first ring, the second ring having an inner annular portion and an outer annular portion, the inner annular portion being configured to support the first ring and having a plurality of through-holes, the outer annular portion being disposed so as to surround the first ring supported on the inner annular portion;
a plurality of substrate lift pins disposed below the substrate support surface;
a plurality of ring lift pins corresponding to the respective substrate lift pins, the plurality of ring lift pins being disposed below the ring support surface to be aligned with the plurality of through-holes, each lift pin having an upper portion having a first width less than the through-hole and a lower portion having a second width greater than the through-hole;
at least one actuator configured to vertically move the substrate lift pins;
at least one connection/separation mechanism configured to switch a connected state and a separated state between the substrate lift pin and the corresponding ring lift pin; and
a controller configured to perform a substrate transfer sequence, a first ring transfer sequence, and a second ring transfer sequence,
wherein the substrate transfer sequence includes:
lifting a substrate on the substrate support surface with the substrate lift pins by vertically moving the substrate lift pins in the separated state,
the first ring transfer sequence includes:
lifting the first ring with the upper portions of the plurality of ring lift pins by simultaneously and vertically moving the substrate lift pins and the ring lift pins in the connected state, and
the second ring transfer sequence includes:
lifting the second ring with the lower portions of the plurality of ring lift pins by simultaneously and vertically moving the substrate lift pins and the ring lift pins in the connected state.

2. The substrate processing apparatus of claim 1, wherein the connection/separation mechanism includes:
a cylinder connected to the ring lift pins; and
an expansion/contraction member connected to the actuator,
wherein the expansion/contraction member is configured to expand in the cylinder to form the connected state and to contract to form the separated state.

3. The substrate processing apparatus of claim 2, wherein the cylinder has a weight such that it cannot be lifted by a vacuum force in the chamber.

4. The substrate processing apparatus of claim 3, wherein the cylinder is made of stainless steel.

5. The substrate processing apparatus of claim 1, wherein the connection/separation mechanism includes:
a cylinder connected to one of the ring lift pin and the actuator; and
an expansion/contraction member connected to the other one of the ring lift pin and the actuator,
wherein the expansion/contraction member is configured to expand in the cylinder to form the connected state and to contract to form the separated state.

6. The substrate processing apparatus of claim 5, wherein the connection/separation mechanism further includes:
a biasing member configured to bias the ring lift pins in a direction of a reaction force to a vacuum force in the chamber.

7. The substrate processing apparatus of claim 1, wherein the first ring is made of a conductive material and the second ring is made of an insulating material.

8. A substrate processing apparatus comprising:
a chamber;
a substrate support disposed in the chamber and having a substrate support surface and a ring support surface;
an edge ring disposed so as to surround a substrate on the substrate support surface;
a plurality of substrate lift pins disposed below the substrate support surface;
a plurality of ring lift pins corresponding to the respective substrate lift pins, the plurality of ring lift pins being disposed below the ring support surface;
at least one actuator configured to vertically move the plurality of substrate lift pins;
at least one connection/separation mechanism configured to switch a connected state and a separated state between the substrate lift pin and the corresponding ring lift pin; and
a controller configured to perform a substrate transfer sequence and an edge ring transfer sequence,
wherein the substrate transfer sequence includes:
lifting the substrate on the substrate support surface with the plurality of substrate lift pins by vertically moving the plurality of substrate lift pins in the separated state, and
the edge ring transfer sequence includes:
lifting the edge ring with the plurality of ring lift pins by simultaneously and vertically moving the plurality of substrate lift pins and the plurality of ring lift pins in the connected state.

9. The substrate processing apparatus of claim 8, wherein the connection/separation mechanism includes:
a cylinder connected to the ring lift pin; and
an expansion/contraction member connected to the actuator,
wherein the expansion/contraction member is configured to expand in the cylinder to form the connected state and to contract to form the separated state.

10. The substrate processing apparatus of claim 9, wherein the cylinder has a weight such that it cannot be lifted by a vacuum force in the chamber.

11. The substrate processing apparatus of claim 10, wherein the cylinder is made of stainless steel.

12. The substrate processing apparatus of claim 8, wherein the connection/separation mechanism includes:
a cylinder connected to one of the ring lift pin and the actuator; and
an expansion/contraction member connected to the other one of the ring lift pin and the actuator,
wherein the expansion/contraction member is configured to expand in the cylinder to form the connected state and to contract to form the separated state.

13. The substrate processing apparatus of claim 12, wherein the connection/separation mechanism further includes:
a biasing member configured to bias the ring lift pin in a direction of a reactive force to a vacuum force in the chamber.

14. A substrate processing system comprising:
a transfer device; and
a substrate processing apparatus,
wherein the transfer device includes:
a transfer chamber; and
a transfer robot disposed in the transfer chamber and having an end effector,
wherein the substrate processing apparatus includes:
a substrate processing chamber configured to communicate with the transfer chamber;
a substrate support disposed in the substrate processing chamber and having a substrate support surface and a ring support surface;
an edge ring disposed so as to surround a substrate on the substrate support surface;
a plurality of substrate lift pins disposed below the substrate support surface;
a plurality of ring lift pins corresponding to the respective substrate lift pins, the plurality of ring lift pins being disposed below the ring support surface;
at least one actuator configured to vertically move the plurality of substrate lift pins;
at least one connection/separation mechanism configured to switch a connected state and a separated state between the substrate lift pin and the corresponding ring lift pin; and
a controller configured to perform a substrate transfer sequence and an edge ring transfer sequence,
wherein the substrate transfer sequence includes:
lifting the substrate on the substrate support surface with the substrate lift pins by vertically moving the substrate lift pins in the separated state;
receiving the lifted substrate with the end effector; and
transferring the substrate received by the end effector from the substrate processing chamber to the transfer chamber, and
the edge ring transfer sequence includes:
lifting the edge ring with the ring lift pins by simultaneously and vertically moving the substrate lift pins and the ring lift pins in the connected state;
receiving the lifted edge ring with the end effector; and
transferring the edge ring received by the end effector from the substrate processing chamber to the transfer chamber.

15. The substrate processing system of claim 14, wherein the connection/separation mechanism includes:
a cylinder connected to the ring lift pin; and
an expansion/contraction member connected to the actuator,
wherein the expansion/contraction member is configured to expand in the cylinder to form the connected state and to contract to form the separated state.

16. The substrate processing system of claim 15, wherein the cylinder has a weight such that it cannot be lifted by a vacuum force in the substrate processing chamber.

17. The substrate processing system of claim 16, wherein the cylinder is made of stainless steel.

18. The substrate processing system of claim 14, wherein the end effector has a U-shape in plan view, and
the plurality of substrate lift pins are disposed inside the end effector when the end effector receives the substrate or the edge ring.

19. The substrate processing system of claim 14, wherein the end effector has a U-shape in plan view, and
at least two of the plurality of substrate lift pins are disposed outside the end effector when the end effector receives the substrate or the edge ring.
